(19) United States
(12) Patent Application Publication
(10) Pub. No.: US 2023/0207265 A1
(43) Pub. Date: Jun. 29, 2023

(54) SUBSTRATE PROCESSING APPARATUS, SUBSTRATE PROCESSING METHOD AND PLASMA GENERATING METHOD

(71) Applicant: SEMES CO., LTD., Cheonan-si (KR)

(72) Inventors: Shant ARAKELYAN, Cheonan-si (KR); Ja Myung Gu, Cheonan-si (KR); Ogsen Galstyan, Cheonan-si (KR)

(73) Assignee: SEMES CO., LTD., Cheonan-si (KR)

(21) Appl. No.: 18/145,413

(22) Filed: Dec. 22, 2022

(30) Foreign Application Priority Data
Dec. 23, 2021 (KR) 10-2021-0186572

(51) Int. Cl. H01J 37/32

(52) U.S. Cl. CPC H01J 37/32165; H01J 37/32128; H01J 37/32568; H01J 37/3244; H01J 2237/032; H01J 2237/334

(57) ABSTRACT

Provided is a substrate processing apparatus. The substrate processing apparatus may include a chamber having an inner space, an electrode configured to generate plasma in the inner space, and a power supply unit configured to apply an RF voltage to the electrode, in which the power supply unit may include a first power supply configured to apply a first pulse voltage having a first frequency to the electrode, a second power supply configured to apply a second pulse voltage having a second frequency different from the first frequency to the electrode, a third power supply configured to apply an RF voltage having a third frequency different from the first frequency and the second frequency, and a phase control member for controlling at least one of the phases of the first pulse voltage and the second pulse voltage.

### CROSS-REFERENCE TO RELATED APPLICATIONS

This application claims priority to and the benefit of Korean Patent Application No. 10-2021-0186572 filed in the Korean Intellectual Property Office on Dec. 23, 2021, the entire contents of which are incorporated herein by reference.

### TECHNICAL FIELD

The present invention relates to a substrate processing apparatus, a substrate processing method, and a plasma generating method.

### BACKGROUND ART

In order to manufacture a semiconductor device, a substrate is subjected to various processes such as photolithography, etching, ashing, ion implantation, thin film deposition, and cleaning to form a desired pattern on the substrate. Among the processes, the etching process is a process of removing a selected heating region from among films formed on the substrate, and wet etching and dry etching are used. For the dry etching thereof, an etching device using plasma is used. Plasma refers to an ionized gas state composed of ions or electrons, radicals, and the like. The plasma is generated by very high temperatures, or strong RF electromagnetic fields. In the RF electromagnetic fields, an RF generator applies an RF voltage to one of electrodes facing each other. The RF generator applies a continuous wave RF or pulsed RF to the electrode. When the continuous wave RF is applied to the electrode, an RF voltage having a constant amplitude is always applied to the electrode. In contrast, when the pulsed RF is applied to the electrode, the RF state applied to the electrode has a high-state or a low or zero state. The high-state is referred to as a pulse-on, and the low or zero state is referred to as a pulse-off. The pulsed RF has a characteristic of using the pulse-off state. In the pulse-on state, high ion energy is generated as in the case where the continuous wave RF is applied, and as a result, a wafer is etched. In the pulse-off state, as a generated plasma sheath disappears, electrons are cooled and the density of electrons and cations decreases. Compared to the continuous wave RF, the pulsed RF has an advantage of obtaining results such as an etching form or mask shape coming out in a state close to the vertical. However, recently, as a line width of a pattern formed on a substrate such as a wafer has been narrowed, it is required to further improve substrate processing uniformity using plasma.

### SUMMARY OF THE INVENTION

An object of the present invention is to provide a substrate processing apparatus, a substrate processing method, and a plasma generating method capable of efficiently processing a substrate. Another object of the present invention is to provide a substrate processing apparatus, a substrate processing method, and a plasma generating method capable of improving substrate processing uniformity by plasma.

Yet another object of the present invention is to provide a substrate processing apparatus, a substrate processing method, and a plasma generating method capable of having both advantages when generating plasma using a continuous wave RF and when generating plasma using a pulsed RF.

Yet another object of the present invention is to provide a substrate processing apparatus, a substrate processing method, and a plasma generating method capable of allowing a shape of an object to be etched by plasma to come out in a state close to the vertical.

Yet another object of the present invention is to provide a substrate processing apparatus, a substrate processing method, and a plasma generating method capable of improving the uniformity of a plasma density generated according to a region of the substrate when generating plasma using a pulsed RF.

The problem to be solved by the present invention is not limited to the above-mentioned problems, and the problems not mentioned will be clearly understood by those skilled in the art from the present specification and the accompanying drawings.

An exemplary embodiment of the present invention provides a substrate processing apparatus. The substrate processing apparatus may include a chamber having an inner space, an electrode configured to generate plasma in the inner space, and a power supply unit configured to apply an RF voltage to the electrode, in which the power supply unit may include a first power supply configured to apply a first pulse voltage having a first frequency to the electrode, a second power supply configured to apply a second pulse voltage having a second frequency different from the first frequency to the electrode, a third power supply configured to apply an RF voltage having a third frequency different from the first frequency and the second frequency, and a phase control member for controlling at least one of the phases of the first pulse voltage and the second pulse voltage.

According to the exemplary embodiment, the phase control member may control at least one of the phase of the first pulse voltage and the phase of the second pulse voltage so that the phase of the first pulse voltage and the phase of the second pulse voltage are different from each other. According to the exemplary embodiment, the phase control member may control at least one of the phase of the first pulse voltage and the phase of the second pulse voltage so that a difference between the phase of the first pulse voltage and the phase of the second pulse voltage may become 90° to 270°.

According to the exemplary embodiment, the phase control member may control at least one of the phase of the first pulse voltage and the phase of the second pulse voltage so that a difference between the phase of the first pulse voltage and the phase of the second pulse voltage may become 180°.

According to the exemplary embodiment, the first power supply may be configured to apply the first pulse voltage having the first frequency higher than the second frequency to the electrode, and the phase control member may be configured to shift the phase of the second pulse voltage based on the first pulse voltage to generate a difference between the phase of the first pulse voltage and the phase of the second pulse voltage.

According to the exemplary embodiment, the third power supply may be configured to apply a third pulse voltage having a third frequency lower than the first frequency and the second frequency to the electrode.

According to the exemplary embodiment, the first power supply may be configured to apply the first pulse voltage having the first frequency which is a frequency greater than the second frequency to the electrode, and the third power supply may be configured to synchronize the third pulse voltage with the first pulse voltage and apply the third pulse voltage to the electrode. According to the exemplary embodiment, the phase control member may be connected to the first power supply and the second power supply among the first power supply, the second power supply, and the third power supply.

According to the exemplary embodiment, the substrate processing apparatus may further include a lower electrode unit having a lower electrode that is the electrode and supporting the substrate in the inner space and an upper electrode unit having an upper electrode facing the lower electrode and providing a supply path of the process gas supplied to the inner space.

According to the exemplary embodiment, the substrate processing apparatus may further include a gas supply unit for supplying process gas to the inner space, in which gas supply unit may include a gas storage unit for storing the process gas, a gas inlet port disposed to overlap with a central region of the lower electrode unit and supplying the process gas, when viewed from the top, and a gas supply line for supplying the process gas stored in the gas storage unit to the gas inlet port.

According to the exemplary embodiment, the first power supply may be configured to further apply a first continuous voltage having the first frequency to the electrode, and the second power supply may be configured to further apply a second continuous voltage having the second frequency to the electrode.

Another exemplary embodiment of the present invention provides a method for processing a substrate. The substrate processing method may include carrying the substrate into an inner space of a chamber in which the substrate is processed and applying an RF voltage to an electrode for generating plasma to the inner space, in which the RF voltage may include a first pulse voltage having a first frequency, a second pulse voltage having a second frequency different from the first frequency, and a third voltage having a third frequency lower than the first frequency and the second frequency in the electrode.

According to the exemplary embodiment, a phase of the first pulse voltage and a phase of the second pulse voltage may be different from each other.

According to the exemplary embodiment, the duty ratios of the first pulse voltage and the second pulse voltage may be 50%, and a difference between the phase of the first pulse voltage and the phase of the second pulse voltage may be 180°.

According to the exemplary embodiment, the duty ratios of the first pulse voltage and the second pulse voltage may be different from each other, in which the first pulse voltage and the second pulse voltage may be alternately applied to the electrode to have a phase difference.

According to the exemplary embodiment, the first frequency may be higher than the second frequency, and a phase difference between the first pulse voltage and the second pulse voltage may be generated by shifting the second pulse voltage of the first pulse voltage and the second pulse voltage by a phase control member.

According to the exemplary embodiment, the first frequency may be higher than the second frequency, the third voltage may be a pulse voltage, and the third voltage may be applied to the electrode in synchronization with the first pulse voltage.

Yet another exemplary embodiment of the present invention provides a method for generating plasma for processing a substrate. The method may include supplying process gas to an inner space of a chamber and applying an RF voltage to an electrode for forming an electric field in the inner space to excite the process gas into a plasma state, in which a first voltage having a first frequency and a second voltage having a second frequency different from the first frequency may be alternately applied to the electrode, and a third voltage having a third frequency lower than the first frequency and the second frequency may be applied to the electrode while the first voltage or the second voltage is applied to the electrode.

According to the exemplary embodiment, the first voltage and the second voltage may be pulse voltages, and a phase difference between the first voltage and the second voltage may be 90° to 270°.

According to the exemplary embodiment, the phase difference between the first voltage and the second voltage may be generated by phase-shifting the second voltage based on the first voltage, and the phase difference between the first voltage and the second voltage may be 180°.

According to an exemplary embodiment of the present invention, it is possible to effectively process a substrate.

According to an exemplary embodiment of the present invention, it is possible to improve substrate processing uniformity by plasma.

According to an exemplary embodiment of the present invention, it is possible to have both advantages when generating plasma using a continuous wave RF and when generating plasma using a pulsed RF.

According to an exemplary embodiment of the present invention, it is possible to allow a shape of an object to be etched by plasma to come out in a state close to the vertical.

According to an exemplary embodiment of the present invention, it is possible to improve the uniformity of a plasma density generated according to a region of the substrate when generating plasma using a pulsed RF.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram schematically illustrating a substrate processing apparatus according to an exemplary embodiment of the present invention.

FIG. 2 is a graph showing a voltage waveform of a first pulse voltage applied to a lower electrode by a first power supply of FIG. 1.

FIG. 3 is a graph showing a voltage waveform of a second pulse voltage applied to the lower electrode by a second power supply of FIG. 1.

FIG. 4 is a graph showing a voltage waveform of a third pulse voltage applied to the lower electrode by a third power supply of FIG. 1.

FIG. 5 is a graph showing a first exemplary embodiment in which a phase control member controls a phase of the second pulse voltage.

FIG. 6 is a graph showing a second exemplary embodiment in which the phase control member controls a phase of the second pulse voltage.

FIG. 7 is a graph showing a third exemplary embodiment in which the phase control member controls a phase of the second pulse voltage.

FIG. 8 is a graph showing a fourth exemplary embodiment in which the phase control member controls a phase of the second pulse voltage.

FIG. 9 is a graph showing plasma density for each region of a substrate generated according to the exemplary embodiments of FIGS. 5 to 8.

FIGS. 10 to 13 are diagrams illustrating spatial distribution of plasma generated in a chamber according to the exemplary embodiments of FIGS. 5 to 8 through simulation.

FIG. 14 is a graph showing a comparison of plasma density, plasma sheath, and electric-field uniformity for each region of the substrate according to the exemplary embodiments of FIGS. 5 to 8.

FIG. 15 is a graph showing a plasma sheath voltage magnitude for each region of the substrate according to the exemplary embodiments of FIGS. 5 to 8.

FIG. 16 is a graph showing an electric-field intensity for each region of the substrate according to the exemplary embodiments of FIGS. 5 to 8.

FIG. 17 is a graph showing waveforms of voltages applied to a lower electrode according to an exemplary embodiment of the present invention.

FIG. 18 is a graph showing waveforms of voltages applied to a lower electrode according to another exemplary embodiment of the present invention.

FIG. 19 is a graph showing waveforms of voltages applied to a lower electrode according to another exemplary embodiment of the present invention.

FIG. 20 is a graph showing waveforms of voltages applied to a lower electrode according to another exemplary embodiment of the present invention.

FIG. 21 is a graph showing waveforms of voltages applied to a lower electrode according to another exemplary embodiment of the present invention.

### DETAILED DESCRIPTION

Advantages and features of the present invention, and methods for accomplishing the same will be more clearly understood from exemplary embodiments to be described below in detail with reference to the accompanying drawings. However, the present invention is not limited to the exemplary embodiments set forth below, and may be embodied in various different forms. The exemplary embodiments are just for rendering the disclosure of the present invention complete and are set forth to provide a complete understanding of the scope of the invention to a person with ordinary skill in the technical field to which the present invention pertains, and the present invention will only be defined by the scope of the claims.

All terms (including technical or scientific terms) used herein have the same meanings as meanings which are generally received by universal techniques in the related art to which the invention pertains, unless defined. Terms defined in generally dictionaries shall be construed to have the same meanings as those in the context of related arts and/or the present application, and shall not be generalized or construed in excessively formal meanings unless clearly defined herein.

It is also to be understood that the terminologies used herein are for the purpose of describing exemplary embodiments and are not intended to limit the present disclosure. Unless particularly stated otherwise in the present specification, a singular form also includes a plural form. It will be appreciated that the word “comprise” and/or verb variations such as “comprises” or “comprising” used herein means that the aforementioned compositions, components, constituent elements, steps, operations and/or devices do not exclude the existence or addition of one or more other compositions, components, constituent elements, steps, operations and/or devices. In this specification, the term ‘and/or’ indicates each of listed configurations or various combinations thereof.

Terms, such as first and second, are used for describing various constituent elements, but the constituent elements are not limited by the terms. The terms are used only for distinguishing one component from the other component. For example, without departing from the scope of the invention, a first constituent element may be named as a second constituent element, and similarly a second constituent element may be named as a first constituent element.

The singular expression includes the plural expression unless the context clearly dictates otherwise. Accordingly, shapes, sizes, and the like of the elements in the drawing may be exaggerated for clearer description.

The terms ‘unit’ and ‘module’ used herein may refer to hardware components such as software, FPGA or ASIC, as a unit for processing at least one function or operation. However, the ‘unit’ and ‘module’ are not a meaning limited to software or hardware. The ‘unit’ and ‘module’ may be configured to be on an addressable storage medium and may be configured to replay one or more processors.

As one example, the ‘unit’ and ‘module’ may include components such as software components, object oriented software components, class components, and task components, processes, functions, attributes, procedures, subroutines, segments of a program code, drivers, firmware, microcodes, circuits, data, databases, data structures, tables, arrays, and variables. The functions provided by the components and the ‘unit’ and ‘module’ may be separately performed by a plurality of components and ‘units’ and ‘modules,’ or may be integrated with other additional components.

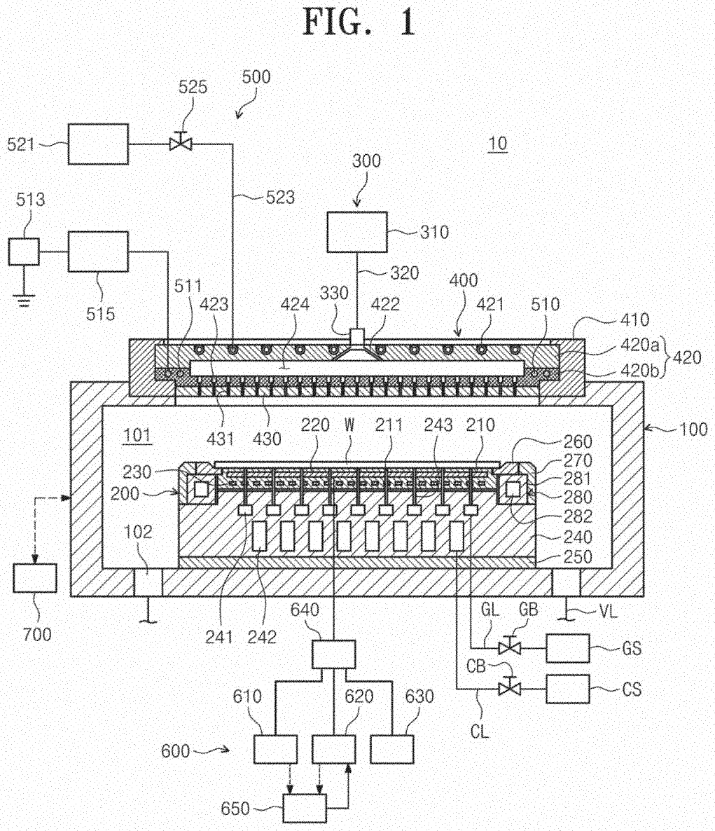

Hereinafter, an exemplary embodiment of the present invention will be described with reference to FIGS. 1 to 21.

FIG. 1 is a diagram schematically illustrating a substrate processing apparatus according to an exemplary embodiment of the present invention.

Referring to FIG. 1, a substrate processing apparatus 10 processes a substrate W using plasma. For example, the substrate processing apparatus 10 may perform an etching process on the substrate W. The substrate processing apparatus 10 may include a chamber 100, a lower electrode unit 200, a gas supply unit 300, an upper electrode unit 400, a temperature control unit 500, a power supply unit 600, and a controller 700.

The chamber 100 may have an inner space 101. The substrate W may be processed in the inner space 101. The substrate W may be processed by plasma in the inner space 101. The substrate W may be etched by plasma. The plasma may be transferred to the substrate W to etch a film formed on the substrate W.

An inner wall of the chamber 100 may be coated with a material having excellent plasma resistance. The chamber 100 may be grounded. The chamber 100 may be formed with a carry-in/carry-out port (not illustrated) through which the substrate W may be carried in or out. The carry-in/carry-out port may be selectively opened and closed by a door (not illustrated). While the substrate W is processed, the inner space 101 may be closed by the carry-in/carry-out port. In addition, while the substrate W is processed, the inner space 101 may have a vacuum pressure atmosphere.

An exhaust hole 102 may be formed in the bottom of the chamber 100. The atmosphere of the inner space 101 may be exhausted through the exhaust hole 102. The exhaust hole 102 may be connected to an exhaust line VL for providing decompression to the inner space 101. Process gas, plasma, process by-products, and the like supplied to the inner space 101 may be exhausted to the outside of the substrate processing apparatus 10 through the exhaust hole 102 and the exhaust line VL. In addition, the pressure in the inner space 101 may be controlled by the decompression provided by the exhaust line VL. For example, the pressure of the inner space 101 may be controlled by the decompression provided by the gas supply unit 300 to be described below and the exhaust line VL. When the pressure of the inner space 101 is to be further reduced, the decompression provided by the exhaust line VL may be increased or the supply amount of the process gas supplied by the gas supply unit 300 per unit time may be reduced. On the contrary, when the pressure of the inner space 101 is to be further increased, the decompression provided by the exhaust line VL may be decreased or the supply amount of the process gas supplied by the gas supply unit 300 per unit time may be increased.

The lower electrode unit 200 may support the substrate W. The lower electrode unit 200 may support the substrate W in the inner space 101. The lower electrode unit 200 may have one of counter electrodes forming an electric field in the inner space 101. In addition, the lower electrode unit 200 may be an electrostatic chuck ESC capable of adsorbing and fixing the substrate W using an electrostatic force.

The lower electrode unit 200 may include a dielectric plate 210, a lower electrode 220, a heater 230, a support plate 240, an insulating plate 250, a ring member 260, an insulating body 270, and a coupling ring 280.

The dielectric plate 210 may be provided above the support unit 200. The electrode plate 210 may be provided with an insulating material. For example, the dielectric plate 210 may be made of a material including ceramic or quartz. The dielectric plate 210 may have a seating surface for supporting the substrate W. When viewed from the top, the seating surface of the dielectric plate 210 may have an area smaller than that of a lower surface of the substrate W. A lower surface of an edge region of the substrate W placed on the dielectric plate 210 may face an upper surface of the ring member 260 to be described below.

The dielectric plate 210 is formed with a first supply flow path 211. The first supply flow path 211 may be formed to extend from the upper surface to the lower surface of the dielectric plate 210. A plurality of first supply flow paths 211 are spaced apart from each other, and may be provided as a passage through which a heat transfer medium is supplied to the lower surface of the substrate W. For example, the first supply flow path 211 may fluid-communicate with a first circulation flow path 241 and a second supply flow path 243 to be described below.

In addition, a separate electrode (not illustrated) for adsorbing the substrate W to the dielectric plate 210 may be embedded in the dielectric plate 210. A direct current may be applied to the electrode. An electrostatic force acts between the electrode and the substrate by the applied current, and the substrate W may be adsorbed to the dielectric plate 210 by the electrostatic force. The lower electrode 220 may be an electrode that forms an electric field in the inner space 101. The lower electrode 220 may have a substantially plate shape. The lower electrode 220 may be one of counter electrodes that form the electric field in the inner space 101. The lower electrode 220 may be provided to face an upper electrode 420 to be described below, which is the other one of the counter electrodes. An electric field formed in the inner space 101 by the lower electrode 220 may excite process gas supplied from the gas supply unit 300 to be described below to generate plasma. The electrode plate 220 may be provided in the dielectric plate 210.

The heater 230 is electrically connected to an external power supply (not illustrated). The heater 230 generates heat by resisting a current applied from an external power supply. The generated heat may be transmitted to the substrate W through the dielectric plate 210. The substrate W may be maintained at a predetermined temperature by the heat generated in the heater 230. The heater 230 may include a spiral coil. The heaters 230 may be embedded in the dielectric plate 210 at regular intervals.

The support plate 240 is located below the dielectric plate 210. The support plate 240 may be provided with an aluminum material. The upper surface of the support plate 240 may be stepped so that a center region is higher than an edge region. The center region of the upper surface of the support plate 240 has an area corresponding to the lower surface of the dielectric plate 210 and may adhere to the lower surface of the dielectric plate 210. The support plate 240 may be formed with a first circulation flow path 241, a second circulation flow path 242 and a second supply flow path 243.

The first circulation flow path 241 may be provided as a passage for circulating a heat transfer medium. The heat transfer medium stored in a heat transfer medium storage unit GS may be supplied to the first circulation flow path 241 through a medium supply line GL. A medium supply valve GB may be provided in the medium supply line GL. According to an on/off of the medium supply valve GB or a change in opening rate, the heat transfer medium is supplied to the first circulation flow path 241 or a supply flow rate per unit time of the heat transfer medium supplied to the first circulation flow path 241 may be controlled. The heat transfer medium may include helium (He) gas.

The first circulation flow path 241 may be formed in a spiral shape inside the support plate 240. Alternatively, the first circulation flow path 241 may be disposed so that ring-shaped flow paths having different radii have the same center. The respective first circulation flow paths 241 may communicate with each other. The first circulation flow paths 241 are formed at the same height. The second circulation flow path 242 may be provided as a passage for circulating a cooling fluid. The cooling fluid stored in a cooling fluid storage unit CS may be supplied to the first circulation flow path 242 through a fluid supply line CL. A fluid supply valve CB may be provided in the fluid supply line CL. According to an on/off of the fluid supply valve CB or a change in opening rate, the cooling fluid is supplied to the second circulation flow path 242 or a supply flow rate per unit time of the cooling fluid supplied to the second circulation flow path 242 may be controlled. The cooling fluid may be cooling water or cooling gas. The cooling fluid supplied to the second circulation flow path 242 may cool the support plate 240 to a predetermined temperature. The support plate 240 cooled to the predetermined temperature may maintain the temperature of the dielectric plate 210 and/or the substrate W at a predetermined temperature.

The second circulation flow path 242 may be formed in a spiral shape inside the support plate 240. Alternatively, the second circulation flow path 242 may be disposed so that ring-shaped flow paths having different radii have the same center. The respective second circulation flow paths 242 may communicate with each other. The second circulation flow path 242 may have a cross-sectional area greater than that of the first circulation flow path 241. The second circulation flow paths 242 are formed at the same height. The second circulation flow path 242 may be located below the first circulation flow path 241.

The second supply flow path 243 extends upward from the first circulation flow path 241 and is provided as the upper surface of the support plate 240. The second supply flow paths 243 are provided in the number corresponding to the first supply flow paths 211, and may fluid-communicate with the first circulation flow path 241 and the first supply flow path 211.

The insulating plate 250 is provided below the support plate 240. The insulating plate 250 is provided in a size corresponding to the support plate 240. The insulating plate 250 is located between the support plate 240 and the bottom surface of the chamber 100. The insulating plate 250 is provided with an insulating material and may electrically insulate the support plate 240 and the chamber 100 from each other.

The ring member 260 may be disposed below the edge region of the substrate W. At least a part of the ring member 260 may be disposed below the edge region of the substrate W. The ring member 260 may have a ring shape as a whole. An upper surface of the ring member 260 may include an inner upper surface, an outer upper surface, and an inclined upper surface. The inner upper surface may be an upper surface adjacent to a central region of the substrate W. The outer upper surface may be an upper surface farther from the central region of the substrate W than the inner upper surface. The inclined upper surface may be an upper surface provided between the inner upper surface and the outer upper surface. The inclined upper surface may be an upper surface inclined upward in a direction far away from the center of the substrate W. The ring member 260 may expand an electric field forming region so that the substrate W is located at the center of a region where plasma is formed. The ring member 260 may be a focus ring.

The insulating body 270 may be configured to surround the ring member 260 when viewed from the top. The insulating body 270 may be provided with an insulating material. The insulating body 270 may be provided to include an insulating material such as quartz or ceramic.

A cable may be connected to the coupling ring 280. The coupling ring 280 may be disposed below the ring member 260 and the insulating body 270. The coupling ring 280 may be surrounded by the ring member 260, the insulating body 270, the support plate 240, and the dielectric plate 210. The coupling ring 280 may include a ring body 281 and a ring electrode 282. The ring body 281 may be provided with an insulating material (e.g., quartz or ceramic). A cable or the like provided with a variable capacitor is connected to the ring electrode 282 to control an impedance.

The gas supply unit 300 may supply process gas to the chamber 100. The gas supply unit 300 may include a gas storage unit 310, a gas supply line 320, and a gas inlet port 330. The gas supply line 320 connects the gas storage unit 310 and the gas inlet port 330 and supplies the process gas stored in the gas storage unit 310 to the gas inlet port 330. The gas inlet port 330 may be provided in a gas supply hole 422 formed in the upper electrode 420.

The upper electrode unit 400 may have the upper electrode 420 facing the lower electrode 220. In addition, the above-described gas supply unit 300 may be connected to the upper electrode unit 400 to provide a part of a supply path of the process gas supplied by the gas supply unit 300. The upper electrode unit 400 may include a support body 410, an upper electrode 420, and a distribution plate 430.

The support body 410 may be fastened to the chamber 100. The support body 410 may be a body to which the upper electrode 420 and the distribution plate 430 of the upper electrode unit 400 are fastened. The support body 410 may be a medium through which the upper electrode 420 and the distribution plate 430 may be provided in the chamber 100.

The upper electrode 420 may be an electrode facing the lower electrode 220. The upper electrode 420 may be provided to face the lower electrode 220. An electric field may be formed in a space between the upper electrode 420 and the lower electrode 220. The formed electric field may generate plasma by exciting process gas supplied to the inner space 101. The upper electrode 420 may be provided in a disk shape. The upper electrode 420 may include an upper plate 410a and a lower plate 410b. The upper electrode 420 may be grounded. However, the present invention is not limited thereto, and an RF power supply (not illustrated) may be connected to the upper electrode 420 to apply an RF voltage.

The lower surface of the upper plate 412a is stepped so that the center region is higher than the edge region. Gas supply holes 422 are formed in the central region of the upper plate 420a. The gas supply holes 422 are connected to the gas inlet port 330 and supply process gas to a buffer space 424. The cooling flow path 421 may be formed inside the upper plate 410a. The cooling flow path 421 may be formed in a spiral shape. Alternatively, the cooling flow path 421 may be disposed so that ring-shaped flow paths having different radii have the same center. The temperature control unit 500 to be described below may supply a cooling fluid to the cooling flow path 421. The supplied cooling fluid may circulate along the cooling flow path 421 and cool the upper plate 420a.

The lower plate 420b is located below the upper plate 420a. The lower plate 420b is provided in a size corresponding to the upper plate 420a and is located to face the upper plate 420a. The upper surface of the lower plate 410b is stepped so that the center region is lower than the edge region. The upper surface of the lower plate 420b and the lower surface of the upper plate 420a are combined with each other to form the buffer space 424. The buffer space 424 is provided as a space where the gas supplied through the gas supply holes 422 temporarily stays before being supplied into the chamber 100. Gas supply holes 423 are formed in the central region of the lower plate 420b. A plurality of gas supply holes 423 are spaced apart from each other at regular intervals. The gas supply holes 423 are connected to the buffer space 424.

The distribution plate 430 is located below the lower plate 420b. The distribution plate 430 is provided in a disk shape. Distribution holes 431 are formed in the distribution plate 430. The distribution holes 431 are provided from the upper surface to the lower surface of the distribution plate 430. The distribution holes 431 are provided in the number corresponding to the gas supply holes 423, and are located to correspond to positions where the gas supply holes 423 are located. The process gas staying in the buffer space 424 is uniformly supplied into the chamber 100 through the gas supply holes 423 and the distribution holes 431.

The temperature control unit 500 may control the temperature of the upper electrode 420. The temperature control unit 500 may include a heating member 511, a heating power supply 513, a filter 515, a cooling fluid supply unit 521, a fluid supply channel 523, and a valve 525.

The heating member 511 may heat the lower plate 420b. The heating member 511 may be a heater. The heating member 511 may be a resistive heater. The heating member 511 may be embedded in the lower plate 420b. The heating power supply 513 may generate power for heating the heating member 511. The heating power supply 513 may heat the heating member 511 to heat the lower plate 420b. The heating power supply 513 may be a DC power supply. The filter 515 may block the RF voltage (power) applied by the power supply unit 600 to be described below from being transmitted to the heating power supply 513.

The cooling fluid supply unit 521 may store a cooling fluid for cooling the upper plate 520a. The cooling fluid supply unit 521 may supply the cooling fluid to the cooling flow path 421 through the fluid supply channel 523. The cooling fluid supplied to the cooling flow path 421 may lower the temperature of the upper plate 420a while flowing along the cooling flow path 421. In addition, a fluid valve 525 may be provided in the fluid supply channel 523 to control the cooling fluid of the cooling fluid supply unit 521 or the supply amount of the cooling fluid per unit time. The fluid valve 525 may be an on/off valve or a flow rate control valve.

The power supply unit 600 may apply a radio frequency (RF) voltage to the lower electrode 220. The power supply unit 600 may apply the RF voltage to the lower electrode 220 to form an electric field in the inner space 101. The electric field formed in the inner space 101 may excite process gas supplied to the inner space 101 to generate plasma. The power supply unit 600 may include a first power supply 610, a second power supply 620, a third power supply 630, a matching member 640, and a phase control member 650.

The first power supply 610 may apply a voltage having a first frequency to the lower electrode 220. The first frequency of the voltage generated by the first power supply 610 may be higher than a second frequency and a third frequency of voltages generated by the second power supply 620 and the third power supply 630 to be described below. The first power supply 610 may be a source RF for generating plasma in the inner space 101. The first frequency may be 60 MHz. The first power supply 610 may be configured to apply a first continuous voltage having the first frequency or a first pulse voltage having the first frequency to the lower electrode 220. The first continuous voltage may be a continuous wave (CW) RF. In addition, the first pulse voltage may be a pulsed RF.

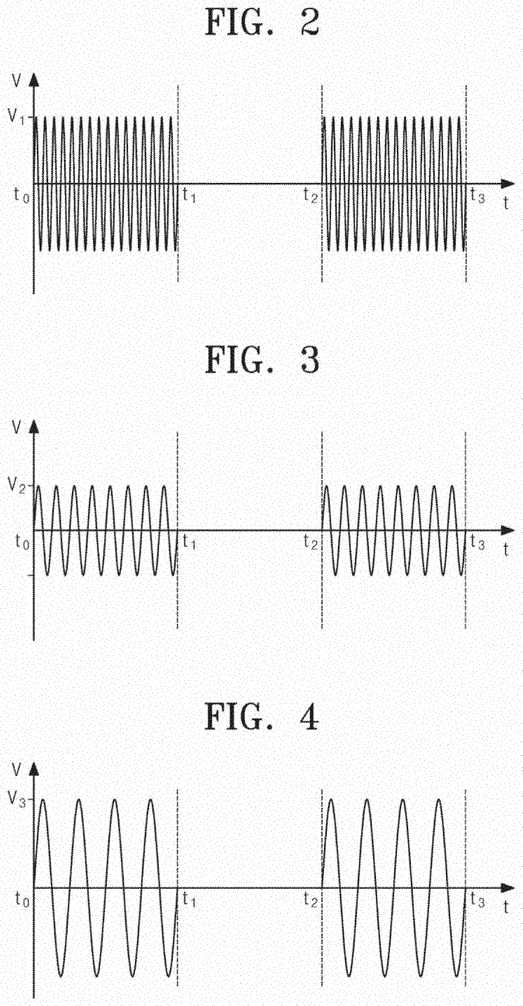

FIG. 2 is a graph showing a voltage waveform of the first pulse voltage applied to the lower electrode by the first power supply of FIG. 1. In FIG. 2, for example, it is illustrated that the state of the first pulse voltage is a high state or a zero state. In FIG. 2, the high state may mean a voltage state at t0 to t1 and t2 to t3. In addition, the zero state may mean a voltage state at t1 to t2. The high state may be represented as a pulse-on. The zero state may be represented as a pulse-off. In addition, the pulse-on state and the pulse-off state may be alternately shown. In addition, the duration of the pulse-on state and the duration of the pulse-off may be the same as each other. In addition, in the above example, it has been illustrated as an example that the pulse-off state is a zero state, but the pulse-off state may also be a low state (specifically, a state in which the frequency is the same as that of the high state, but the magnitude of the voltage is smaller than that of the high state). In addition, a duty ratio of the first pulse voltage applied by the first power supply 610 may be 50%. The duty ratio may mean time in the pulse-on state/(time in the pulse-on state+time in the pulse-off state). The intensity of the first pulse voltage may have a first magnitude V1.

Referring back to FIG. 1, the second power supply 620 may apply a voltage having a second frequency to the lower electrode 220. The second frequency of the voltage generated by the second power supply 620 may be smaller than the first frequency of the voltage generated by the first power supply 610 described above, and may be greater than the third frequency of the voltage generated by the third power supply 630. The second power supply 620 may be a source RF for generating plasma in the inner space 101 together with the first power supply 610. The second frequency may be 2 MHz to 9.8 MHz.

The second power supply 620 may be configured to apply a second continuous voltage having the second frequency or a second pulse voltage having the second frequency to the lower electrode 220. The second continuous voltage may be a continuous wave (CW) RF. In addition, the second pulse voltage may be a pulsed RF.

FIG. 3 is a graph showing a voltage waveform of the second pulse voltage applied to the lower electrode by the second power supply of FIG. 1. In FIG. 3, for example, it is illustrated that the state of the third pulse voltage is a high state or a zero state. In addition, FIG. 3 shows voltage waveforms when the phase of the second pulse voltage is not shifted by the phase control member 650 to be described below. In FIG. 3, the high state may mean a voltage state at t0 to t1 and t2 to t3. In addition, the zero state may mean a voltage state at t1 to t2. The high state may be represented as a pulse-on. The zero state may be represented as a pulse-off. In addition, the pulse-on state and the pulse-off state may be alternately shown. In addition, the duration of the pulse-on state and the duration of the pulse-off may be the same as each other. In addition, in the above example, it has been illustrated as an example that the pulse-off state is a zero state, but the pulse-off state may also be a low state (specifically, a state in which the frequency is the same as that of the high state, but the magnitude of the voltage is smaller than that of the high state). The magnitude of the second pulse voltage may be a second magnitude V2. The second magnitude V2 may be smaller than the first magnitude V1. However, it is not limited thereto, and the second magnitude V2 may be equal to or larger than the first magnitude V1. In addition, the duty ratio of the second pulse voltage may be 50%.

In addition, the second pulse voltage may have the same duration of the pulse-on state and duration of the pulse-off state as those of the first pulse voltage.

Referring back to FIG. 1, the third power supply 630 may apply a voltage having a third frequency to the lower electrode 220. The third frequency of the voltage generated by the third power supply 630 may be smaller than the first frequency of the voltage generated by the first power supply 610 and the second frequency of the voltage generated by the second power supply 620 described above. The second power supply 620 may be a bias RF used to accelerate ions of plasma in the inner space 101 together with the first power supply 610. The third frequency may be 40 kHz.

The third power supply 630 may be configured to apply a third continuous voltage having the third frequency or a third pulse voltage having the third frequency to the lower electrode 220. The third continuous voltage may be a continuous wave (CW) RF. In addition, the third pulse voltage may be a pulsed RF. The duty ratio of the third pulse voltage may be 50%. In addition, the magnitude of the third pulse voltage may have a third magnitude V3. The third magnitude V3 may be larger than the first magnitude V1 and the second magnitude V2. Unlike this, the third magnitude V3 may be equal to the first magnitude V1 and the second magnitude V2 or smaller than the first magnitude V1 and the second magnitude V2.

The controller 700 may control the substrate processing apparatus 10. The controller 700 may control components of the substrate processing apparatus 10. The controller 700 may control the power supply unit 600.

The controller 700 may include a process controller consisting of a microprocessor (computer) for executing a control of the substrate processing apparatus 10, a user interface consisting of a keyboard for performing a command input operation and the like to manage the substrate processing apparatus 10 by an operator, a display for visualizing and displaying an moving situation of the substrate processing apparatus 10, and the like, and a memory unit stored with control programs for executing the processing executed by the substrate processing apparatus 10 by the control of the process controller or programs, that is, processing recipes for executing the processing in each configuration unit according to various data and processing conditions. In addition, the user interface and the memory unit may be connected to the process controller. The processing recipes may be stored in a storage medium of the memory unit, and the storage medium may be a hard disk, and may also be a transportable disk such as a CD-ROM and a DVD, or a semiconductor memory such as a flash memory. In addition, the controller 700 may control the power supply unit 600, that is, the first power supply 610, the second power supply 620, and the third power supply 630 to change the duty ratios of the first pulse voltage, the second pulse voltage, and the third pulse voltage.

FIG. 4 is a graph showing voltage waveforms of the third pulse voltage applied to the lower electrode by the third power supply of FIG. 1. In FIG. 4, for example, it is illustrated that the state of the third pulse voltage is a high state or a zero state. In FIG. 4, the high state may mean a voltage state at t0 to t1 and t2 to t3. In addition, the zero state may mean a voltage state at t1 to t2. The high state may be represented as a pulse-on. The zero state may be represented as a pulse-off. In addition, the pulse-on state and the pulse-off state may be alternately shown. In addition, the duration of the pulse-on state and the duration of the pulse-off may be the same as each other. In addition, in the above example, it has been illustrated as an example that the pulse-off state is a zero state, but the pulse-off state may also be a low state (specifically, a state in which the frequency is the same as that of the high state, but the magnitude of the voltage is smaller than that of the high state).

In addition, the third pulse voltage may have the same duration of the pulse-on state and duration of the pulse-off state as those of the first pulse voltage. In addition, the third pulse voltage may be synchronized with the first pulse voltage. For example, when the first pulse voltage is pulsed-on, the third pulse voltage may also be pulsed-on. In addition, when the first pulse voltage is pulsed-off, the third pulse voltage may also be pulsed-off.

Referring back to FIG. 1, the matching member 640 may perform impedance matching. The matching member 640 is connected to the first power supply 610, the second power supply 620, and the third power supply 630, so that the first power supply 610, the second power supply 620, and the third power supply 630 may perform impedance matching on the voltage applied to the lower electrode 220.

The phase control member 650 may control at least one of phases of the first pulse voltage and the second pulse voltage. The phase control member 650 may shift at least one of phases of the first pulse voltage and the second pulse voltage. For example, the phase control member 650 may shift the phase of the second pulse voltage based on the first pulse voltage so that a difference may occur between the phase of the first pulse voltage and the phase of the second pulse voltage. The phase control member 650 may control at least one of the phase of the first pulse voltage and the phase of the second pulse voltage so that the phase difference between the first pulse voltage and the second pulse voltage is 0° to 360°. More specifically, the phase control member 650 may control at least one of the phase of the first pulse voltage and the phase of the second pulse voltage so that the phase difference between the first pulse voltage and the second pulse voltage is 90° to 270°.

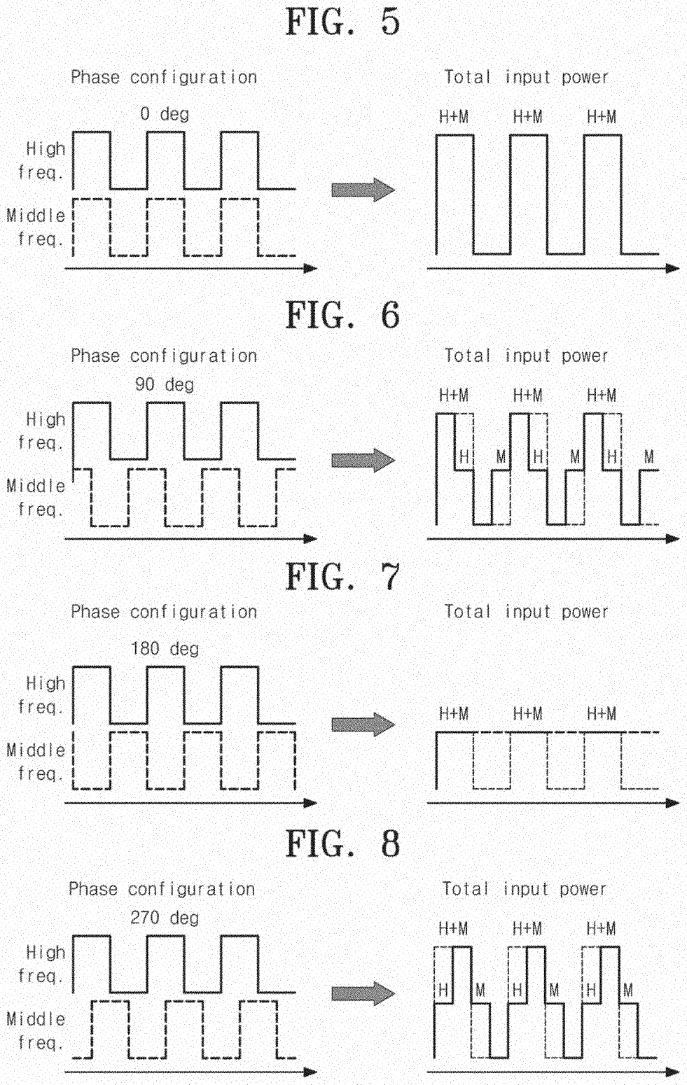

Hereinafter, the first pulse voltage may be represented by High freq. or H, and the second pulse voltage may be represented by Middle freq. or M. In the following phase control exemplary embodiments, the third power supply 630 may apply an RF voltage having a third frequency to the lower electrode 220. The third power supply 630 may apply a third pulse voltage having a third frequency to the lower electrode 220, and the third pulse voltage applied by the third power supply 630 may be synchronized with the first pulse voltage to be applied to the lower electrode 220. In addition, hereinafter, it will be illustrated as an example that the pulse-off state is a zero state, but the pulse-off state may also be a low state as described above. In addition, the duty ratios of the first pulse voltage, the second pulse voltage, and the third pulse voltage in FIGS. 5 to 8 may be 50%.

FIG. 5 is a graph showing a first exemplary embodiment in which the phase control member controls a phase of the second pulse voltage. Referring to FIG. 5, the phase control member 650 may control the phase of the second pulse voltage so that the phase difference between the first pulse voltage and the second pulse voltage becomes 0°. In this case, in a section where the first pulse voltage in the pulse-on state and the second pulse voltage in the pulse-on state overlap with each other, a voltage obtained by combining the first pulse voltage and the second pulse voltage may be applied to the lower electrode 220. A voltage may not be applied to the lower electrode 220 in a section where the first pulse voltage in the pulse-off state and the second pulse voltage in the pulse-off state overlap with each other.

FIG. 6 is a graph showing a second exemplary embodiment in which the phase control member controls a phase of the second pulse voltage. Referring to FIG. 6, the phase control member 650 may control the phase of the second pulse voltage so that the phase difference between the first pulse voltage and the second pulse voltage becomes 90°. In this case, in a section where the first pulse voltage in the pulse-on state and the second pulse voltage in the pulse-on state overlap with each other, a voltage obtained by combining the first pulse voltage and the second pulse voltage may be applied to the lower electrode 220. When the first pulse voltage in the pulse-on state and the second pulse voltage in the pulse-off state overlap with each other, the first pulse voltage may be applied to the lower electrode 220. In a section where the first pulse voltage in the pulse-off state and the second pulse voltage in the pulse-on state overlap with each other, the second pulse voltage may be applied to the lower electrode 220. A voltage may not be applied to the lower electrode 220 in a section where the first pulse voltage in the pulse-off state and the second pulse voltage in the pulse-off state overlap with each other.

FIG. 7 is a graph showing a third exemplary embodiment in which the phase control member controls a phase of the second pulse voltage. Referring to FIG. 7, the phase control member 650 may control the phase of the second pulse voltage so that the phase difference between the first pulse voltage and the second pulse voltage becomes 180° (that is, the second pulse voltage is 100% phase-shifted). In this case, when the first pulse voltage in the pulse-on state and the second pulse voltage in the pulse-off state overlap with each other, the first pulse voltage may be applied to the lower electrode 220. In a section where the first pulse voltage in the pulse-off state and the second pulse voltage in the pulse-on state overlap with each other, the second pulse voltage may be applied to the lower electrode 220.

FIG. 8 is a graph showing a fourth exemplary embodiment in which the phase control member controls a phase of the second pulse voltage. Referring to FIG. 8, the phase control member 650 may control the phase of the second pulse voltage so that the phase difference between the first pulse voltage and the second pulse voltage becomes 270°. In this case, when the first pulse voltage in the pulse-on state and the second pulse voltage in the pulse-off state overlap with each other, the first pulse voltage may be applied to the lower electrode 220. In a section where the first pulse voltage in the pulse-on state and the second pulse voltage in the pulse-on state overlap with each other, a voltage obtained by combining the first pulse voltage and the second pulse voltage may be applied to the lower electrode 220. In a section where the first pulse voltage in the pulse-off state and the second pulse voltage in the pulse-on state overlap with each other, the second pulse voltage may be applied to the lower electrode 220. A voltage may not be applied to the lower electrode 220 in a section where the first pulse voltage in the pulse-off state and the second pulse voltage in the pulse-off state overlap with each other.

Hereinafter, an effect of shifting the phase of the second pulse voltage of the second frequency applied to the lower electrode 220 according to an exemplary embodiment of the present invention will be described.

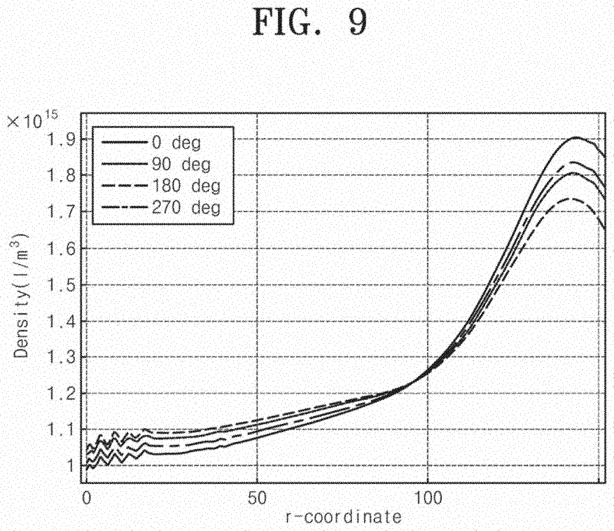

FIG. 9 is a graph showing plasma density for each region of the substrate generated according to the exemplary embodiments of FIGS. 5 to 8. As can be seen with reference to FIG. 9, when the phase of the second pulse voltage is 180°-shifted, it can be seen that a deviation in plasma density between the center of the substrate and the edge of the substrate is relatively smaller than other cases. When the phase of the second pulse voltage is 180°-shifted, the first pulse voltage and the second pulse voltage may be alternately applied to the lower electrode 220. That is, the first pulse voltage and the second pulse voltage may be sequentially applied to the lower electrode 220 while complementing each other.

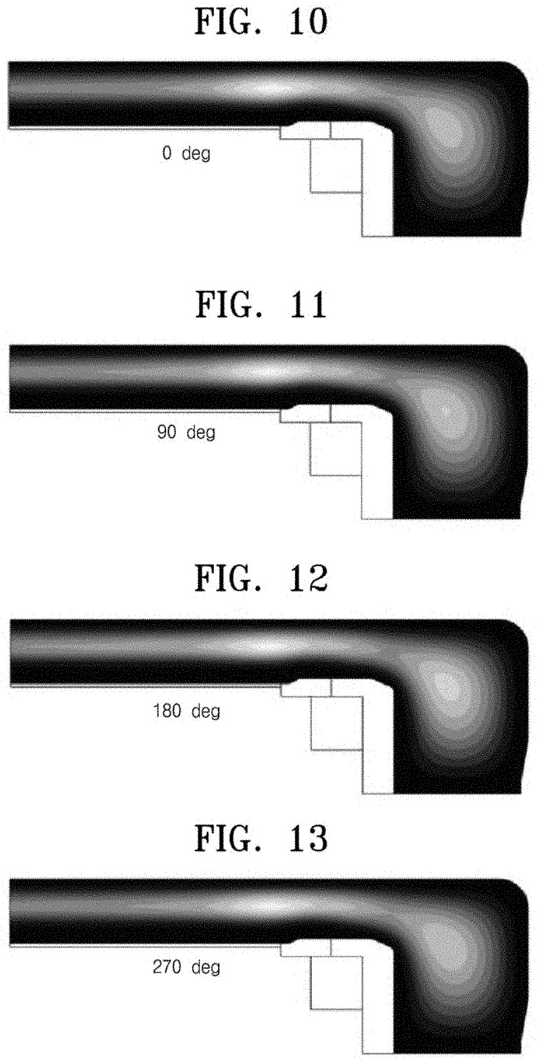

FIGS. 10 to 13 are diagrams illustrating spatial distribution of plasma generated in a chamber according to the exemplary embodiments of FIGS. 5 to 8 through simulation. As can be seen with reference to FIGS. 10 to 13, when the phase of the second pulse voltage is 180°-shifted, it can be seen that a deviation in plasma density between the center of the substrate and the edge of the substrate is relatively smaller than other cases.

When a high-frequency voltage is applied to the lower electrode 220, the process gas supplied to the inner space 101 is excited into a plasma state in a relatively short time. On the other hand, when an intermediate-frequency voltage is applied to the lower electrode 220, it may take a relatively long time to excite the process gas supplied toward the inner space 101, specifically, the central region of the substrate W, into a plasma state. Accordingly, the process gas supplied to the central region of the substrate W is sufficiently moved to the edge region of the substrate W and then excited into a plasma state. That is, when a second pulse voltage having an intermediate frequency is applied to the lower electrode 220, plasma density generated in the edge region of the substrate W may be greater than the plasma density when a first pulse voltage having a high frequency is applied to the lower electrode 220. Accordingly, when the second pulse voltage is 180° phase-shifted, further improved plasma uniformity is provided.

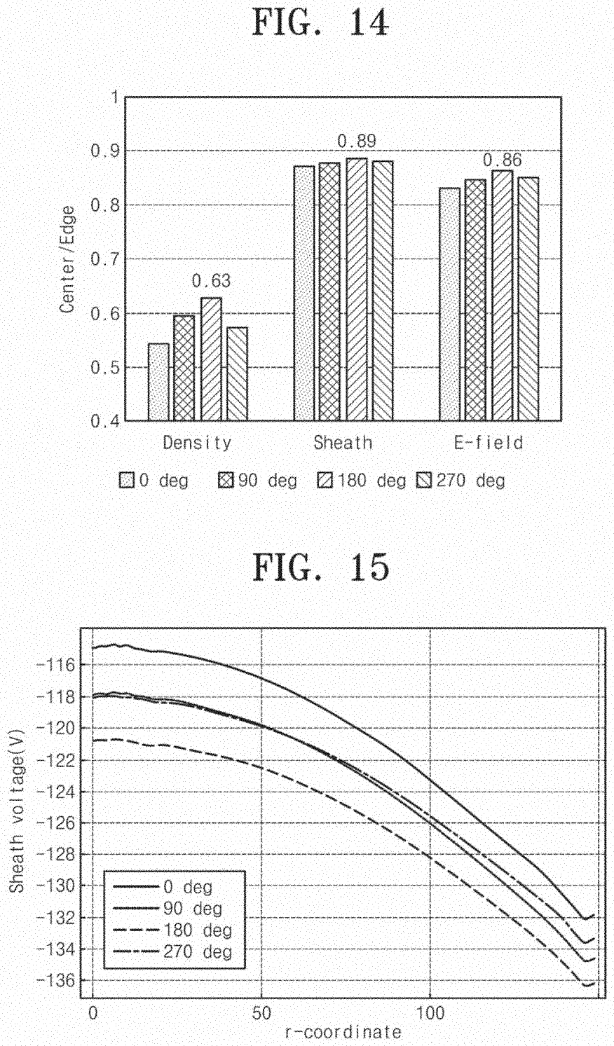

FIG. 14 is a graph showing a comparison of plasma density, plasma sheath, and electric-field uniformity for each region of the substrate according to the exemplary embodiments of FIGS. 5 to 8. Specifically, a density of plasma P in a central region and an edge region of the substrate W, a voltage of a plasma sheath, and the uniformity of an electric field density formed in the inner space 101 are shown. When the value is closer to 1, it is meant that the density of the plasma P in the central region and the edge region of the substrate, the voltage of the plasma sheath, and the density of the electric field formed in the inner space 101 are similar. As can be seen with reference to FIG. 14, when the phase of the second pulse voltage is 180°-shifted, it can be seen that a deviation in plasma density between the center of the substrate and the edge of the substrate, a voltage of the plasma sheath, and the density uniformity of the electric field are improved compared to other cases.

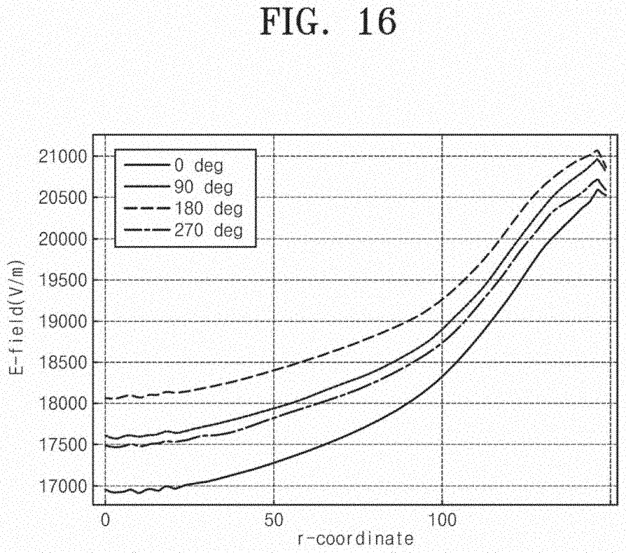

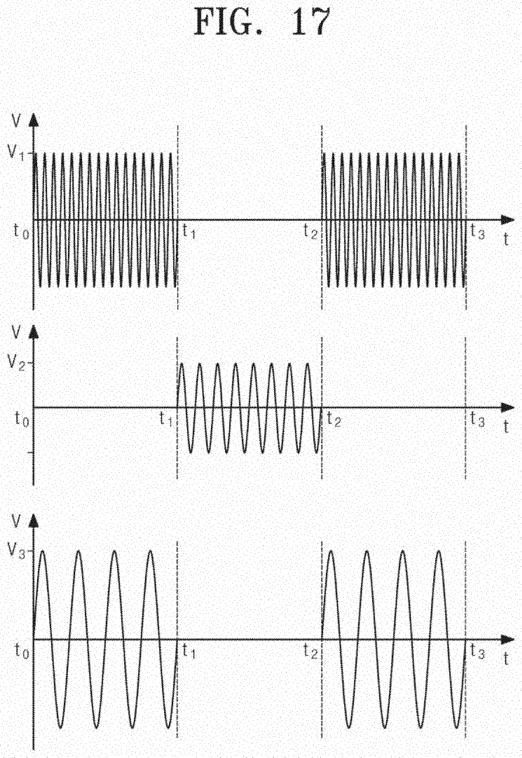

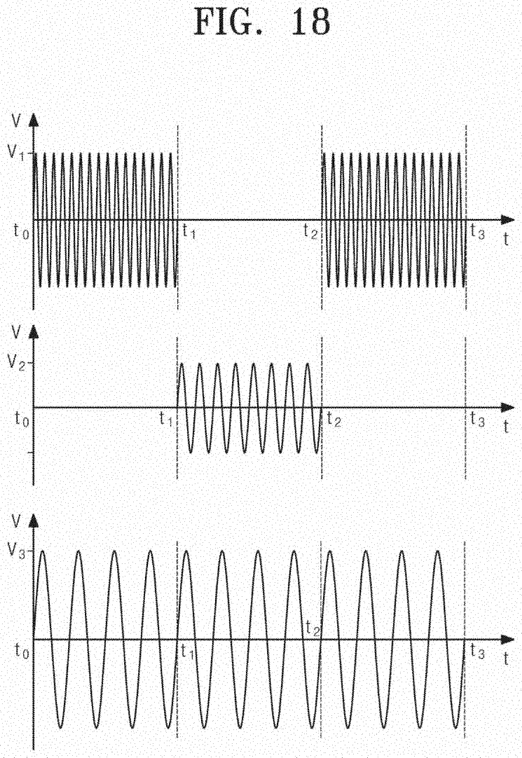

FIG. 15 is a graph showing a plasma sheath voltage magnitude for each region of the substrate according to the exemplary embodiments of FIGS. 5 to 8, and FIG. 16 is a graph showing an electric-field intensity for each region of the substrate according to the exemplary embodiments of FIGS. 5 to 8. FIGS. 15 and 16 illustrate data derived through simulation. As can be seen with reference to FIGS. 15 and 16, it can be seen that the absolute values of the sheath voltage and the electric field of the plasma are maximum when the phase of the second pulse voltage is 180°-shifted. In addition, when the phase of the second pulse voltage is 180°-shifted, since the first pulse voltage and the second pulse voltage are continuously applied to the lower electrode 220, it may be advantageous in terms of plasma stability.

In addition, according to an exemplary embodiment of the present invention, the second pulse voltage having a relatively low frequency may be phase-shifted based on the first pulse voltage having a relatively high frequency so as to perform the phase shift more precisely. In addition, according to an exemplary embodiment of the present invention, the third pulse voltage applied by the third power supply 630, which is the bias RF, may be synchronized with the first pulse voltage as illustrated in FIG. 17.

In a substrate processing method or a plasma generation method according to an exemplary embodiment of the present invention, process gas is supplied to the inner space 101 of the chamber 100 and an electric field is formed in the inner space 101, but an RF voltage is applied to the lower electrode 220 to excite the process gas into a plasma state. The plasma may be transferred to the substrate W to process the substrate W. A first pulse voltage having a first frequency and a second pulse voltage having a second frequency are alternately applied to the lower electrode 220 to generate plasma, and a third pulse voltage having a third frequency lower than the first frequency and the second frequency may be applied to the lower electrode 220 to accelerate plasma ions and process the substrate W.

Relatively much plasma is generated in the central region of the substrate W in the section where the first pulse voltage is applied, and relatively much plasma is generated in the edge region of the substrate W in the section where the second pulse voltage is applied. In the case of the first pulse voltage, due to the high frequency, the process gas supplied to the vicinity of the central region of the substrate W is relatively quickly excited into a plasma state, and in the case of the second pulse voltage, due to the relatively low frequency, the process gas supplied to the vicinity of the central region of the substrate W is diffused toward the edge region of the substrate W and then excited into the plasma state.

The third pulse voltage attracts and accelerates ions in the plasma. That is, in a section where the first pulse voltage is applied, ions of the plasma generated while the plasma is excited are attracted. This may slightly lower the degree to which the plasma is excited. In the section where the second pulse voltage is applied, the plasma is excited without attracting ions by the second pulse voltage. That is, as the third pulse voltage is synchronized with the first pulse voltage, the uniformity of plasma density may be further improved.

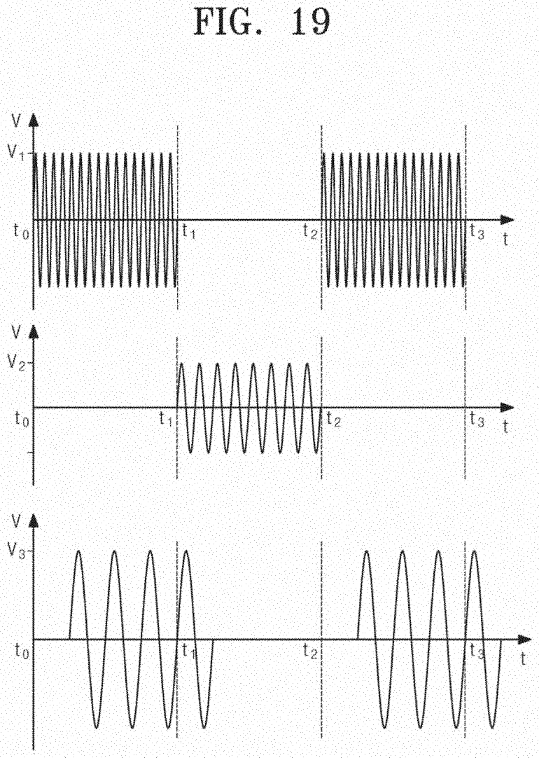

In the above example, it has been described as an example that the voltage applied by the third power supply 630 is the pulse voltage, but is not limited thereto. For example, the voltage applied by the third power supply 630 may be a continuous voltage as illustrated in FIG. 18.

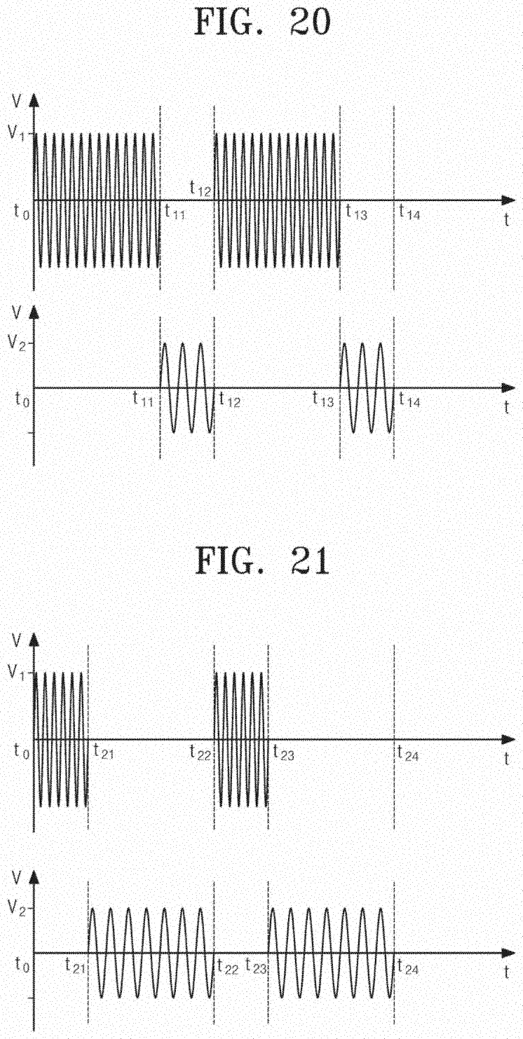

In the above example, it has been described as an example that the third pulse voltage is synchronized with the first pulse voltage, but is not limited thereto. For example, as shown in FIG. 19, the phase of the third pulse voltage may be different from that of the first pulse voltage. In the above example, it has been described as an example that the duty ratios of the first pulse voltage and the second pulse voltage are 50%, and the phase difference between the two voltages is 180° (i.e., the phase shift of the second pulse voltage is 100%), but is not limited thereto. For example, as shown in FIG. 20, the duty ratios of the first pulse voltage and the second pulse voltage may be different from each other. For example, the duty ratio of the first pulse voltage is 70%, the duty ratio of the second pulse voltage is 30%, and the second pulse voltage may be 100% phase-shifted with respect to the first pulse voltage (i.e., the first pulse voltage and the second pulse voltage may be applied alternately to have a phase difference). In addition, as shown in FIG. 21, the duty ratio of the first pulse voltage may be 30%, and the duty ratio of the second pulse voltage may be 70%. In addition, the first pulse voltage and the second pulse voltage may be applied alternately to have a phase difference.

It is to be understood that the exemplary embodiments are presented to assist in understanding of the present invention, and the scope of the present invention is not limited, and various modified exemplary embodiments thereof are included in the scope of the present invention. The drawings provided in the present invention are only illustrative of an optimal exemplary embodiment of the present invention. The technical protection scope of the present invention should be determined by the technical idea of the appended claims, and it should be understood that the technical protective scope of the present invention is not limited to the literary disclosure itself in the appended claims, but the technical value is substantially affected on the equivalent scope of the invention.

1. A substrate processing apparatus for processing a substrate comprising:
a chamber having an inner space;
an electrode configured to generate plasma in the inner space; and
a power supply unit configured to apply an RF voltage to the electrode,
wherein the power supply unit comprises
a first power supply configured to apply a first pulse voltage having a first frequency to the electrode;
a second power supply configured to apply a second pulse voltage having a second frequency different from the first frequency to the electrode;
a third power supply configured to apply an RF voltage having a third frequency different from the first frequency and the second frequency; and
a phase control member for controlling at least one of the phases of the first pulse voltage and the second pulse voltage.

2. The substrate processing apparatus of claim 1, wherein the phase control member controls at least one of the phase of the first pulse voltage and the phase of the second pulse voltage so that the phase of the first pulse voltage and the phase of the second pulse voltage are different from each other.

3. The substrate processing apparatus of claim 2, wherein the phase control member controls at least one of the phase of the first pulse voltage and the phase of the second pulse voltage so that a difference between the phase of the first pulse voltage and the phase of the second pulse voltage becomes 90° to 270°.

4. The substrate processing apparatus of claim 3, wherein the phase control member controls at least one of the phase of the first pulse voltage and the phase of the second pulse voltage so that a difference between the phase of the first pulse voltage and the phase of the second pulse voltage becomes 180°.

5. The substrate processing apparatus of claim 1, wherein the first power supply is configured to apply the first pulse voltage having the first frequency higher than the second frequency to the electrode, and
the phase control member is configured to shift the phase of the second pulse voltage based on the first pulse voltage to generate a difference between the phase of the first pulse voltage and the phase of the second pulse voltage.

6. The substrate processing apparatus of claim 1, wherein the third power supply is configured to apply a third pulse voltage having a third frequency lower than the first frequency and the second frequency to the electrode.

7. The substrate processing apparatus of claim 6, wherein the first power supply is configured to apply the first pulse voltage having the first frequency, which is a frequency greater than the second frequency, to the electrode, and
the third power supply is configured to synchronize the third pulse voltage with the first pulse voltage and apply the third pulse voltage to the electrode.

8. The substrate processing apparatus of claim 1, wherein the phase control member is connected to the first power supply and the second power supply among the first power supply, the second power supply, and the third power supply.

9. The substrate processing apparatus of claim 1, further comprising:
a lower electrode unit having a lower electrode that is the electrode and supporting the substrate in the inner space; and
an upper electrode unit having an upper electrode facing the lower electrode and providing a supply path of the process gas supplied to the inner space.

10. The substrate processing apparatus of claim 9, further comprising:
a gas supply unit for supplying process gas to the inner space,
wherein the gas supply unit comprises
a gas storage unit for storing the process gas;
a gas inlet port disposed to overlap with a central region of the lower electrode unit and supplying the process gas, when viewed from the top; and
a gas supply line for supplying the process gas stored in the gas storage unit to the gas inlet port.

11. The substrate processing apparatus of claim 1, wherein the first power supply is configured to further apply a first continuous voltage having the first frequency to the electrode, and
the second power supply is configured to further apply a second continuous voltage having the second frequency to the electrode.

12.-20. (canceled)
